(19) United States
(12) Patent Application Publication
(10) Pub. No.: US 2026/0033223 A1
(43) Pub. Date: Jan. 29, 2026

(54) DISPLAY DEVICE, ELECTRONIC DEVICE INCLUDING DISPLAY DEVICE, AND METHOD OF MANUFACTURING DISPLAY DEVICE

(71) Applicant: Samsung Display Co., LTD., Yongin-si (KR)

(72) Inventors: Nak Cho CHOI, Yongin-si (KR); Won Mo PARK, Yongin-si (KR); Jong Seon PARK, Yongin-si (KR)

(21) Appl. No.: 19/086,799

(22) Filed: Mar. 21, 2025

(30) Foreign Application Priority Data
Jul. 23, 2024 (KR) 10-2024-0097145

(51) Int. Cl. H10K 59/80; B60K 35/22; H10K 59/40; H10K 59/88

(52) U.S. Cl. CPC H10K 59/8792; B60K 35/22; H10K 59/40; H10K 59/873; H10K 59/88; B60K 2360/1434; B60K 2360/1523; B60K 2360/48

(57) ABSTRACT

A display device includes: a display panel including first and second pixels; a light controlling layer on the display panel, and including an alignment key layer, and light blocking layers including first and second light blocking parts; and a window layer on the light controlling layer. The first light blocking part encloses an entirety of the first pixel in a plan view. The second light blocking part is opened at a first side of the second pixel in a first direction, and encloses a second side of the first pixel in a second direction. The display device is to operate in a first mode in which the first pixel is to provide light, or a second mode in which the second pixel is to provide light. The alignment key layer is located in a same layer as that of at least one of the light blocking layers.

### CROSS-REFERENCE TO RELATED APPLICATION

The present application claims priority to and the benefit of Korean Patent Application No. 10-2024-0097145, filed on Jul. 23, 2024, in the Korean Intellectual Property Office, the entire disclosure of which is incorporated by reference herein.

### BACKGROUND

### 1. Field

Aspects of embodiments of the present disclosure relate to a display device, an electronic device including the display device, and a method of manufacturing the display device.

### 2. DESCRIPTION OF RELATED ART

Recently, as interest in information display has increased, research and development on display devices have been continuously conducted. Display devices may be applied to various fields, such as in-vehicle infotainment systems.

A display device may be manufactured based on a plurality of processes. As such, it may be desirable for layers of the display device to be precisely aligned with each other during the time periods in which the processes are performed.

The above information disclosed in this Background section is for enhancement of understanding of the background of the present disclosure, and therefore, it may contain information that does not constitute prior art.

### SUMMARY

Embodiments of the present disclosure may be directed to a display device and a method of manufacturing the display device, in which a manufacturing process may be simplified, thereby reducing production costs.

Embodiments of the present disclosure may be directed to a display device that may enhance user safety and improve visibility characteristics, so that the display device may be suitably applied to in-vehicle infotainment systems, and a method of manufacturing the display device.

Embodiments of the present disclosure may be directed to a display device and a method of manufacturing the display device, in which an alignment key for performing a manufacturing process may be suitably provided.

Embodiments of the present disclosure may be directed to a display device in which dead space may be reduced, and thus, allowing a visible surface area to be expanded, and a method of manufacturing the display device.

According to one or more embodiments of the present disclosure, a display device includes: a display panel including a first pixel, and a second pixel spaced from the first pixel; a light controlling layer on the display panel, and including an alignment key layer, and light blocking layers including a first light blocking part and a second light blocking part; and a window layer on the light controlling layer. The first light blocking part encloses an entirety of the first pixel in a plan view. The second light blocking part is opened at a first side of the second pixel in a first direction, and encloses a second side of the first pixel in a second direction different from the first direction. The display device is configured to operate in a first mode in which the first pixel is configured to provide light, or a second mode in which the second pixel is configured to provide light. The alignment key layer is located in a same layer as that of at least one of the light blocking layers.

In an embodiment, the window layer may be configured to be aligned utilizing the alignment key layer.

In an embodiment, the light blocking layers may include a bottom light blocking layer adjacent to the display panel, and a top light blocking layer adjacent to the window layer.

In an embodiment, the alignment key layer may be located in a same layer as that of the bottom light blocking layer.

In an embodiment, a structure in a same layer as those of the light blocking layers may not be located over the alignment key layer.

In an embodiment, the display device may further include an insulating layer on the alignment key layer, the insulating layer including a bent portion in an area overlapping with the alignment key layer in a plan view.

In an embodiment, the alignment key layer may be located in a same layer as that of the top light blocking layer.

In an embodiment, the display device may further include: a passivation layer as a base on which the light blocking layers are located; a protective layer covering the light blocking layers; and an insulating layer on the protective layer. The light blocking layers may include four different layers.

In an embodiment, the display device may further include a display area, and a non-display area enclosing the display area. The alignment key layer may not overlap with a floating conductive structure in a plan view.

In an embodiment, the display device may further include a display area, and a non-display area enclosing the display area. The display panel may include a backplane wire located in the non-display area, the backplane wire having a linear structure. The alignment key layer may not overlap with a conductive structure having an island shape in a plan view.

In an embodiment, the display device may further include a sensing area, and a non-sensing area enclosing the sensing area. The display panel may further include a display layer, and a touch sensor layer on the display layer, the touch sensor layer including a sensing electrode. The touch sensor layer may further include a sensing wire in the non-sensing area, the sensing wire having a linear structure, and being electrically connected to the sensing electrode. The alignment key layer may not overlap with a conductive structure having an island shape in a plan view.

In an embodiment, the display device may further include a display area, and a non-display area enclosing the display area. The non-display area may include a dummy area around the display area. A dummy light blocking layer may be located in the dummy area in a same layer as that of at least one of the light blocking layers.

In an embodiment, the alignment key layer may be located in the dummy area.

In an embodiment, the alignment key layer may include an embossed pattern.

In an embodiment, the alignment key layer may include an intaglio pattern.

In an embodiment, the light blocking layers may include one or more of a black matrix material or an organic black material.

In an embodiment, the alignment key layer and the at least one of the light blocking layers in the same layer as that of the alignment key layer may include the black matrix material, and some of the light blocking layers that are in a different layer from that of the alignment key layer may include the organic black material.

In an embodiment, the display device may further include: a polarization layer between the light controlling layer and the window layer; and a black matrix layer under the window layer. The black matrix layer and the alignment key layer may overlap with each other in a plan view.

In an embodiment, the display panel may include a base layer, and the display device may further include a sensor under the base layer in a display area.

In an embodiment, the light blocking layer may include a lactam-based material.

In an embodiment, the first light blocking part may have a closed-loop shape, and the second light blocking part may have a shape extending in one direction.

In an embodiment, the display device may be implemented as a co-driver display on an in-vehicle infotainment system.

According to one or more embodiments of the present disclosure, a display device includes: a display panel configured to provide light; a light controlling layer on the display panel, and configured to guide a portion of the light provided from the display panel, the light controlling layer including: a light blocking layer configured to block at least another portion of the light; and an alignment key layer in a same layer as that of at least a portion of the light blocking layer, and including a same material as that of the at least the portion of the light blocking layer; and a window layer on the light controlling layer, and configured to be aligned utilizing the alignment key layer.

According to one or more embodiments of the present disclosure, a method of manufacturing a display device includes: providing a display panel; providing, on the display panel, a light controlling layer including an alignment key layer and a light blocking layer; and providing a window layer on the light controlling layer by utilizing the alignment key layer. The light blocking layer is configured to block or guide light provided from the display panel, and the alignment key layer is patterned through a same process as that of at least a portion of the light blocking layer.

In an embodiment, the light blocking layer may include a bottom light blocking layer closest to the display panel, and a top light blocking layer closest to the window layer. The alignment key layer may be embedded in the light controlling layer.

In an embodiment, the method may further include disposing a polarization layer on the light controlling layer, and the providing of the window layer may include discerning a position of the alignment key layer by utilizing light transmitted through the polarization layer.

However, the present disclosure is not limited to the above aspects and features, and the above and additional aspects and features will be set forth, in part, in the detailed description that follows with reference to the drawings, and in part, may be apparent therefrom, or may be learned by practicing one or more of the presented embodiments of the present disclosure.

### BRIEF DESCRIPTION OF THE DRAWINGS

The above and other aspects and features of the present disclosure will be more clearly understood from the following detailed description of the illustrative, non-limiting embodiments with reference to the accompanying drawings.

FIGS. 1 and 2 are schematic sectional views illustrating a display device in accordance with some embodiments.

FIGS. 3 and 4 are schematic plan views illustrating the display device in accordance with some embodiments.

FIG. 5 is a block diagram illustrating an operation mode of the display device in accordance with an embodiment.

FIG. 6 schematically illustrates an example in which the display device is applied to an in-vehicle electronic device in accordance with an embodiment.

FIG. 7 is a diagram schematically illustrating an operation of the display device in a first mode in accordance with an embodiment.

FIG. 8 is a diagram schematically illustrating an operation of the display device in a second mode in accordance with an embodiment.

FIG. 9 is a schematic view illustrating a path of an image to be provided when the display device is applied to the in-vehicle electronic device in accordance with an embodiment.

FIG. 10 is a schematic plan view illustrating a pixel in accordance with an embodiment.

FIGS. 11-14 are schematic sectional views illustrating the display device in accordance with some embodiments.

FIG. 15 is a schematic plan view illustrating a backplane wire and alignment keys in accordance with an embodiment.

FIG. 16 is a schematic plan view illustrating a sensing wire and alignment keys in accordance with an embodiment.

FIG. 17 is a schematic plan view illustrating a display device in accordance with an embodiment.

FIGS. 18 and 19 are schematic sectional views taken along the line C-C′ of FIG. 17.

FIG. 20 is a schematic plan view illustrating a display device in accordance with an embodiment.

FIGS. 21 and 22 are schematic sectional views taken along the line D-D′ of FIG. 20.

FIG. 23 illustrates a schematic plan view and a sectional view of a sensor and a structure adjacent to the sensor in accordance with an embodiment.

FIG. 24 is a flowchart illustrating a method of manufacturing a display device in accordance with an embodiment.

FIGS. 25-27 are schematic sectional views illustrating some processes of the method of manufacturing the display device in accordance with an embodiment.

FIG. 28 is a block diagram of an electronic device according to an embodiment.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

Further, as would be understood by a person having ordinary skill in the art, in view of the present disclosure in its entirety, each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner, unless otherwise stated or implied.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

Further, it should be expected that the shapes shown in the figures may vary in practice depending, for example, on tolerances and/or manufacturing techniques. Accordingly, the embodiments of the present disclosure should not be construed as being limited to the specific shapes shown in the figures, and should be construed considering changes in shapes that may occur, for example, as a result of manufacturing. As such, the shapes shown in the drawings may not depict the actual shapes of areas of the device, and the present disclosure is not limited thereto.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

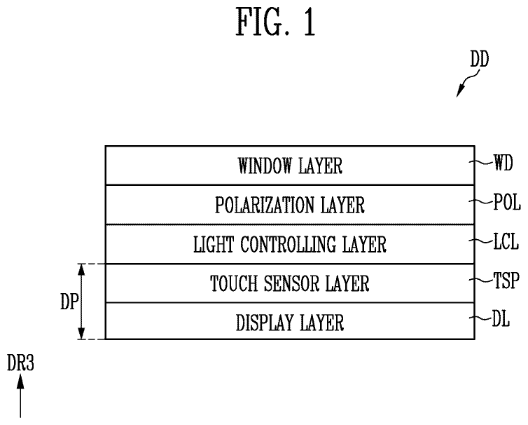

First, a display device DD in accordance with some embodiments will be described in more detail hereinafter with reference to FIGS. 1 to 4.

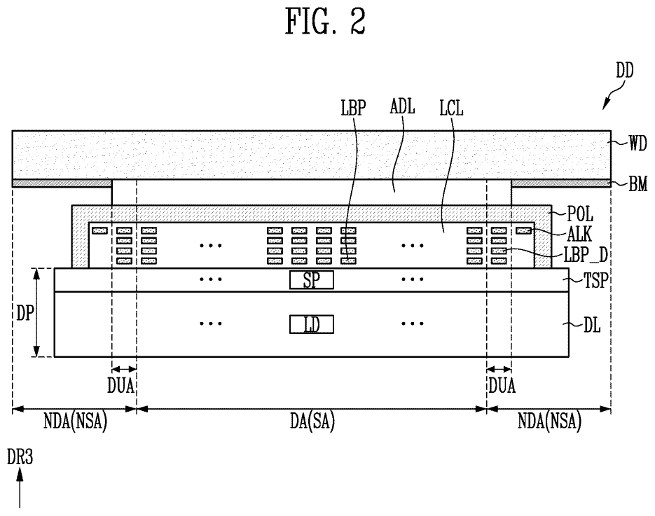

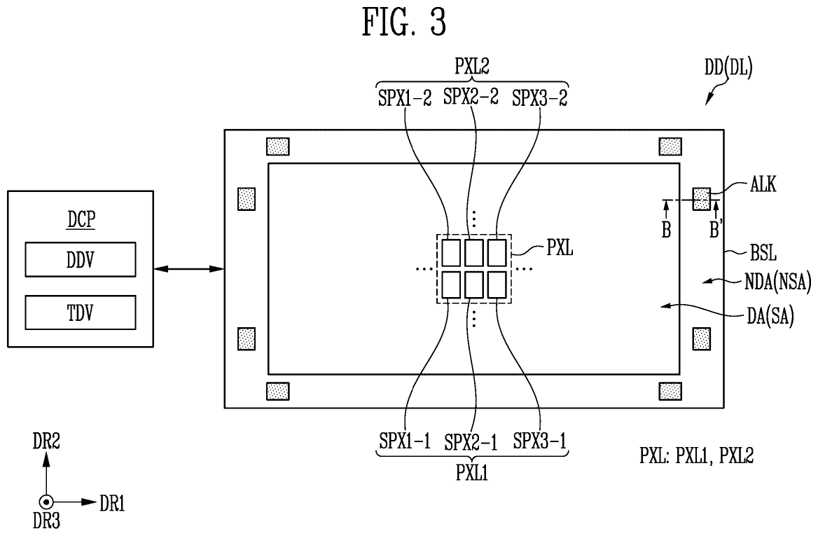

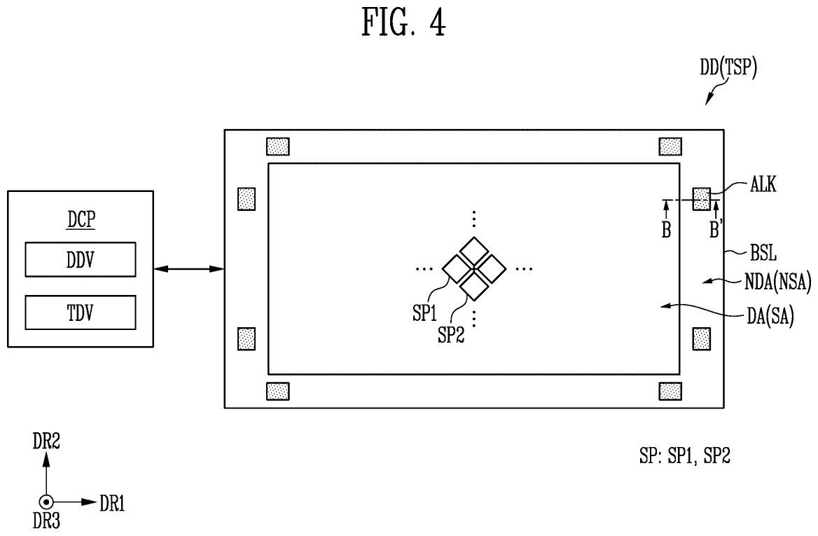

FIGS. 1 and 2 are schematic sectional views illustrating the display device DD in accordance with some embodiments. FIGS. 3 and 4 are schematic plan views illustrating the display device DD in accordance with some embodiments. FIG. 3 illustrates a display layer DL in accordance with an embodiment. FIG. 4 illustrates a touch sensor layer TSP in accordance with an embodiment.

Referring to FIGS. 1 to 4, the display device DD may provide light in response to electrical signals. The display device DD may include a display panel DP. The display panel DP may include a display layer DL and a touch sensor layer TSP. The display device DD may further include a light controlling layer LCL, a polarization layer POL, and a window layer WD.

In an embodiment, the display device DD may include a display area DA, a sensing area SA, a non-display area NDA, and a non-sensing area NSA.

The display area DA may be an area formed to provide light, and may be an area where a pixel PXL is disposed. The non-display area NDA may be an area where no pixel PXL is provided. The non-display area NDA may include a dead space. The non-display area NDA may enclose (e.g., may surround around a periphery of) at least a portion of the display area DA.

The display layer DL may display visual information. The display layer DL may include various suitable light sources to provide light. For example, the display layer DL may include light emitting elements LD disposed in the display area DA, and each of the light emitting elements LD may include (e.g., may be formed of) an organic light emitting diode.

The sensing area SA may be an area capable of sensing a touch input from a user, and may be an area where a sensing electrode SP is disposed. The non-sensing area NSA may be an area where no sensing electrode SP is disposed. The non-sensing area NSA may enclose (e.g., may surround around a periphery of) at least a portion of the sensing area SA.

In an embodiment, the display area DA and the sensing area SA may correspond to each other (e.g., may overlap with each other). Accordingly, in an area where an image is displayed, a touch input from the user may also be sensed.

The touch sensor layer TSP may be directly disposed on the display layer DL, or may be disposed on the display layer DL with a separate layer, such as an adhesive layer or a substrate (or an insulating layer), interposed therebetween.

The touch sensor layer TSP may be disposed on an image display surface of the display layer DL, and may receive the touch input from the user. The touch sensor layer TSP may acquire information about the touch input. The touch sensor layer TSP may recognize a touch event of the display device DD caused by the hand (e.g., a finger) of the user, or caused by a separate input unit (e.g., a separate input device, such as a pen). The touch sensor layer TSP may recognize the touch event using a suitable capacitance method.

The touch sensor layer TSP may sense touch inputs using a mutual capacitance method, or may sense touch inputs using a self-capacitance method. For example, the touch sensor layer TSP may include a sensing electrode. The sensing electrode may include a transmitter (Tx) electrode pattern and a receiver (Rx) electrode pattern.

The light controlling layer LCL may include a suitable structure for controlling a path along which light is emitted, based on an operation mode of the display device DD. For example, the light controlling layer LCL may include light blocking layers LBP, which are respectively formed in a plurality of layers. The light blocking layers LBP may block or guide light provided from the display panel DP. The operation mode of the display device DD will be described in more detail below.

The light controlling layer LCL may include an alignment key layer ALK disposed in the non-display area NDA. The alignment key layer ALK may be a structure for aligning at least one of the structures disposed on the light controlling layer LCL during a process of manufacturing the display device DD.

In an embodiment, the alignment key layer ALK may be a pattern or a mark formed at a suitable position (e.g., a predetermined position). The position of the alignment key layer ALK may function as a reference point for placing the window layer WD.

The non-display area NDA may include a dummy area DUA. The dummy area DUA may be an area where a light emitting element LD is not placed, but a dummy light blocking layer LBP_D is disposed that is formed during a same process as that of the light blocking layer LBP to secure a process margin.

The dummy area DUA may be disposed between the non-display area NDA and the display area DA. The dummy area DUA may be disposed around a periphery of the display area DA, and may enclose (e.g., may surround around the periphery of) the entirety of the display area DA.

The polarization layer POL may be disposed on the light controlling layer LCL. The polarization layer POL may be disposed on an upper surface and side surfaces of the light controlling layer LCL.

The polarization layer POL may include various suitable polarization materials and polarization layers. For example, the polarization layer POL may include a phase retarder (e.g., a N/4 phase retarder), and a linear polarization layer on the phase retarder. However, the present disclosure is not limited thereto. The placement of the polarization layer POL may reduce a risk of a visibility degradation due to external light reflection.

The window layer WD may be disposed on the polarization layer POL. The window layer WD may protect the underlying layers from external impacts, and may provide an input surface and/or a display surface for the user. The window layer WD may transmit light. The window layer WD may be bonded to (e.g., connected to or attached to) the polarization layer POL by various suitable methods, such as by using an adhesive layer.

The window layer WD may be bonded to (e.g., connected to or attached to) the polarization layer POL by an adhesive layer ADL. The adhesive layer ADL may include various suitable adhesive materials, such as an optically clear adhesive (OCA).

The window layer WD may be aligned on the display panel DP using the alignment key layer ALK. For example, the position of the alignment key layer ALK may be recognized or determined using a camera, a sensor, or the like. Accordingly, the window layer WD may be disposed at a desired position (e.g., a preset or predetermined position) based on the position of the alignment key layer ALK.

In an embodiment, the display device DD may further include a black matrix layer BM disposed under the window layer WD. The black matrix layer BM may be disposed between the window layer WD and the polarization layer POL.

In an embodiment, the black matrix layer BM may be disposed in the non-display area NDA other than in the dummy area DUA in a plan view. In an embodiment, the black matrix layer BM may overlap with the alignment key layer ALK in a plan view. The black matrix layer BM may include suitable light blocking materials, such as carbon black, but the present disclosure is not limited thereto.

Referring to FIGS. 3 and 4, the display device DD may include the display layer DL, the touch sensor layer TSP, and a driving circuit part DCP.

For convenience of illustration, FIGS. 2 and 3 illustrate that the driving circuit part DCP is separate from the display layer DL and the touch senor layer TSP, but the present disclosure is not limited thereto. In an embodiment, an entirety of or a portion of the driving circuit part DCP may be implemented integrally with the display layer DL.

In an embodiment, the display device DD may include a base layer BSL, and pixels PXL and sensing electrodes SP disposed on the base layer BSL. The display device DD may include the driving circuit part DCP. The driving circuit part DCP may include a display driver DDV and a touch driver TDV.

The base layer BSL may form a base surface of the display device DD. In an embodiment, the base layer BSL may be a bottom substrate for disposing the layers that form the display device DD thereon. The base layer BSL may be a rigid or flexible substrate or film. For example, the base layer BSL may include a glass material. As another example, the base layer BSL may include a silicon material. As another example, the base layer BSL may include polyimide. However, the present disclosure is not limited thereto.

A plane as used herein may extend in a first direction DR1 and a second direction DR2, and may be defined based on the plane on which the base layer BSL is disposed. In an embodiment, a third direction DR3 may correspond to a thickness direction of the base layer BSL. The third direction DR3 may correspond to a light output direction of the display device DD.

The pixels PXL may include a first pixel PXL1 and a second pixel PXL2. The first pixel PXL1 may provide light when the display device DD is operated in a first mode. The second pixel PXL2 may provide light when the display device DD is operated in a second mode.

The pixel PXL may include sub-pixels. For example, the first pixel PXL1 may include a 1-1-th sub-pixel SPX1-1, a 2-1-th sub-pixel SPX2-1, and a 3-1-th sub-pixel SPX3-1. The second pixel PXL2 may include a 1-2-th sub-pixel SPX1_2, a 2-2-th sub-pixel SPX2_2, and a 3-2-th sub-pixel SPX3_2.

The 1-1-th sub-pixel SPX1-1 and the 1-2-th sub-pixel SPX1-2 may provide light of a first color (e.g., red). The 2-1-th sub-pixel SPX2-1 and the 2-2-th sub-pixel SPX2-2 may provide light of a second color (e.g., green). The 3-1-th sub-pixel SPX3-1 and the 3-2-th sub-pixel SPX3-2 may provide light of a third color (e.g., blue).

The sensing electrodes SP may include a first sensing electrode SP1 extending in the first direction DR1, and a second sensing electrode SP2 extending in the second direction DR2 different from (e.g., crossing) the first direction DR1.

The driving circuit part DCP may drive the display layer DL and the touch sensor layer TSP. For example, the driving circuit part DCP may output a data signal corresponding to image data to the display layer DL. The touch driver TDV may supply sensing signals to the sensing electrodes SP, and may receive a user input signal obtained by sensing a touch input from the user.

In an embodiment, the alignment key layer ALK may be disposed in the non-display area NDA (or in the non-sensing area NSA). The alignment key layer ALK may be disposed in a peripheral portion of the display device DD. For example, the alignment key layer ALK may be disposed adjacent to the corners of the display area DA.

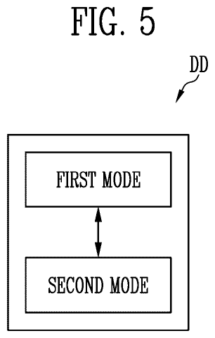

Hereinafter, an operation mode of the display device DD in accordance with an embodiment will be described in more detail with reference to FIGS. 5 to 9. For convenience, the same or substantially the same components and configurations as those described above may be briefly described hereinafter, or redundant description thereof may not be repeated.

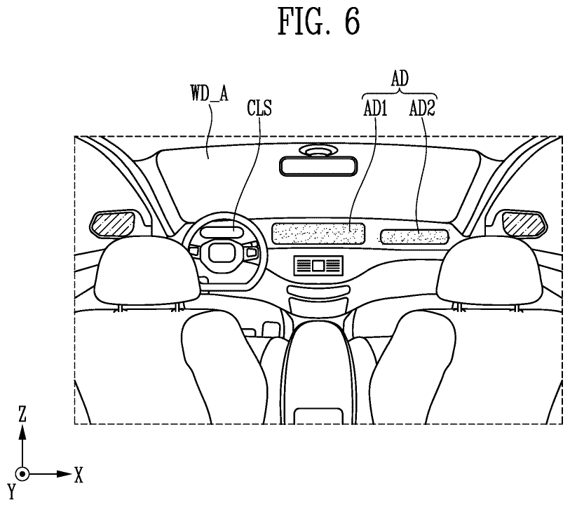

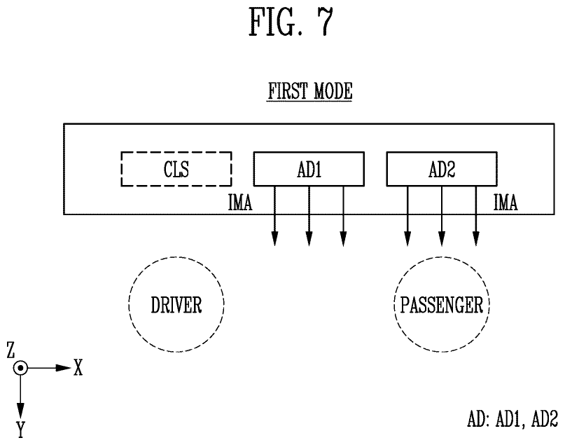

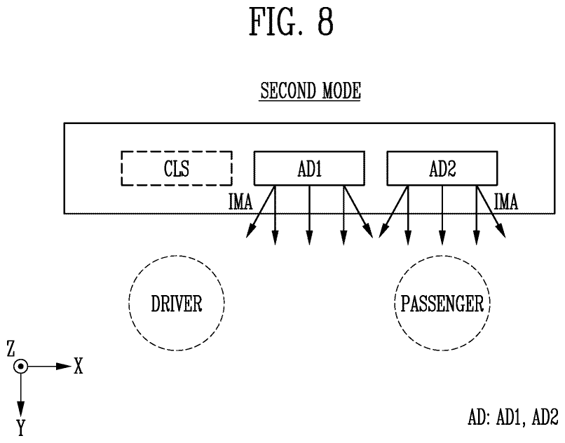

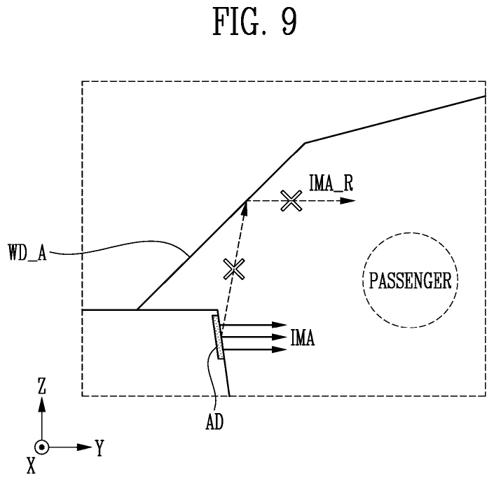

FIG. 5 is a block diagram illustrating an operation mode of the display device DD in accordance with an embodiment. FIG. 6 schematically illustrates an example in which the display device DD is applied to an in-vehicle electronic device in accordance with an embodiment. FIG. 7 is a diagram schematically illustrating an operation of the display device DD in the first mode in accordance with an embodiment. FIG. 8 is a diagram schematically illustrating an operation of the display device DD in the second mode in accordance with an embodiment. FIG. 9 is a schematic view illustrating a path of an image to be provided when the display device DD is applied to the in-vehicle electronic device in accordance with an embodiment.

Referring to FIGS. 5 to 9, the display device DD (e.g., the pixels PXL thereof) in accordance with an embodiment may be operated in the first mode or the second mode. In FIGS. 6 to 9, an X-axial direction X, a Y-axial direction Y, and a Z-axial direction Z are illustrated. Based on the axial directions shown in FIGS. 6 to 9, the positional relationships among a driver, a passenger, and an in-vehicle display device will be described in more detail.

The first mode may be an operation mode in which the first pixel PXL1 provides light. The second mode may be an operation mode in which the second pixel PXL2 provides light.

The first mode and the second mode will be described in conjunction with an example in which the display device DD is applied to an in-vehicle electronic device.

The display device DD in accordance with an embodiment may be applied to the in-vehicle electronic device. The display device DD may be applied to an in-vehicle infotainment system. The display device DD may be applied to a co-driver display AD.

The co-driver display AD may include a first co-driver display AD1 formed in a central portion of a front panel of the vehicle to output various desired information, and a second co-driver display AD2 disposed in front of a passenger seat.

In some embodiments, the in-vehicle electronic device may appropriately control a range of information that is visible to a user based on whether or not the vehicle is in operation.

For example, as users of the vehicle, the driver and the passenger may view images from the front of a cluster CLS and the co-driver display AD. In some embodiments, the driver may not view the co-driver display AD while the vehicle is driving. On the other hand, in some embodiments the driver may be able to view the co-driver display AD while the vehicle is stationary. Furthermore, the cluster CLS may allow the driver to check the cluster CLS regardless of whether or not the vehicle is driving.

In an embodiment, the first mode may be an operation mode of the display device DD in which the driver cannot visually recognize image information IMA output from the co-driver display AD while the vehicle is driving. For example, in the first mode, the co-driver display AD may generally output the image information IMA toward the front, without outputting the image information IMA sideways (e.g., toward the driver) Accordingly, in the first mode, it may be more difficult for the driver to view the co-driver display AD while driving the vehicle.

In an embodiment, the second mode may be an operation mode of the display device DD in which the driver can visually recognize image information IMA output from the co-driver display AD while the vehicle is in operation. For example, in the second mode, the co-driver display AD may generally output the image information IMA toward the front, and may additionally output the image information IMA sideways. Accordingly, in the second mode, the driver may appropriately view the co-driver display AD while the vehicle is in operation.

Accordingly, the display device DD may be suitably applied to the in-vehicle infotainment system, and thus, may enhance user safety.

Referring to FIG. 9, the co-driver display AD may output the image information IMA toward the front. Because an in-vehicle window WD_A may be formed at the front of the vehicle, if (e.g., when) a portion of the image information IMA is applied to the in-vehicle window WD_A, reflective image information IMA_R reflected by the in-vehicle window WD_A may be visible to the passenger (or the driver and the like). In this case, it may be difficult for the display device DD to suitably transmit image information of a desired quality to the passenger and the driver.

In an embodiment, a structure capable of preventing or reducing a risk of an occurrence of the reflective image information IMA_R may be formed around a periphery of the pixels PXL. Accordingly, the risk of a degradation in a display quality of the co-driver display AD due to the reflective image information IMA_R may be reduced.

The first mode, the second mode, and the structure of the display device DD for preventing or reducing a formation of the reflective image information IMA_R described above will be described in more detail below.

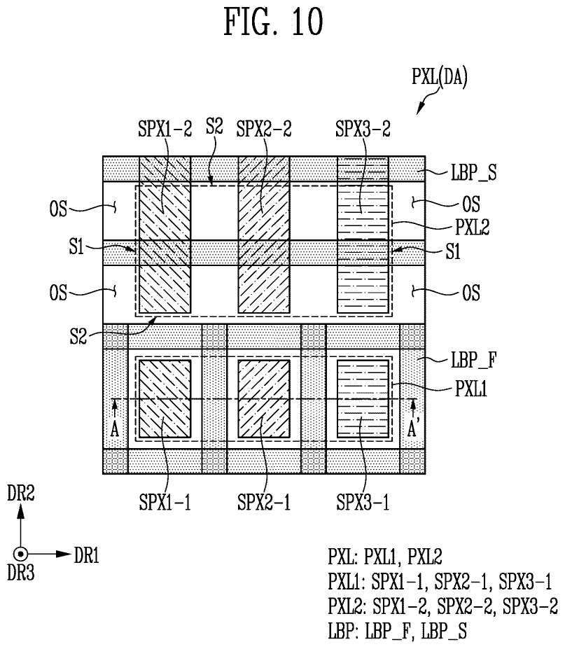

Hereinafter, the display device DD in accordance with some embodiments will be described in more detail with reference to FIGS. 10 to 16.

FIG. 10 is a schematic plan view illustrating a pixel PXL in accordance with an embodiment. FIG. 10 schematically illustrates some of the sub-pixels in the display area DA.

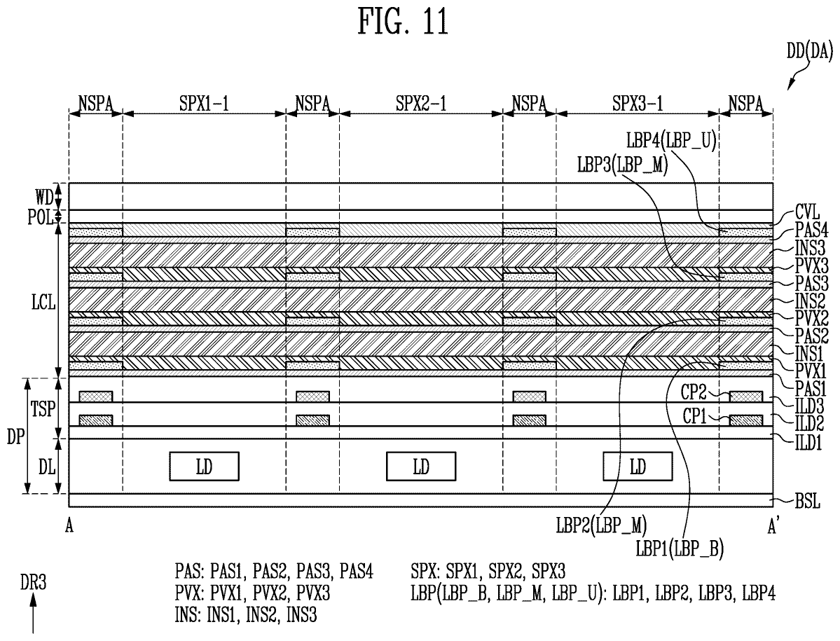

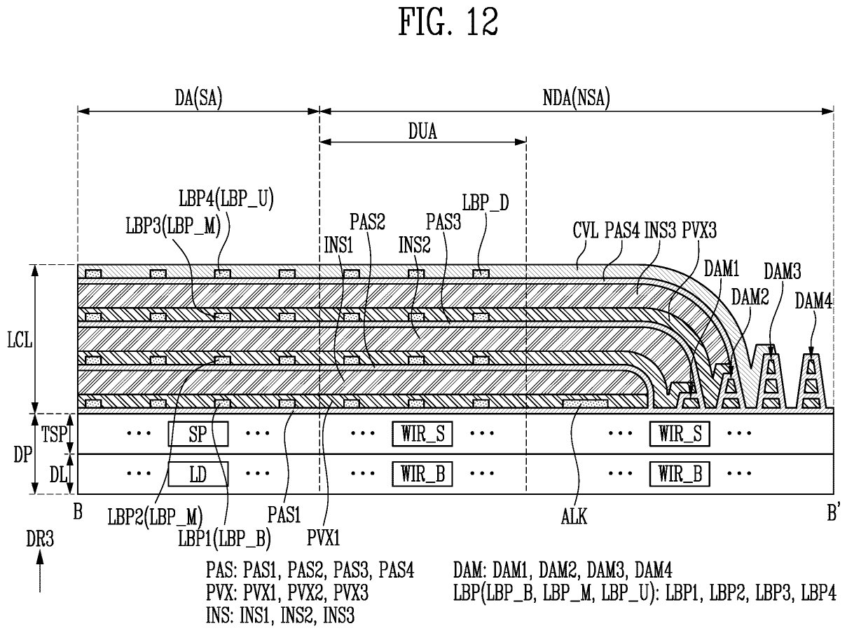

FIGS. 11 through 14 are schematic sectional views illustrating the display device DD in accordance with some embodiments. FIG. 11 is a schematic sectional view taken along the line A-A′ of FIG. 10. FIGS. 12 to 14 are schematic sectional views taken along the line B-B′ of FIGS. 3 and 4.

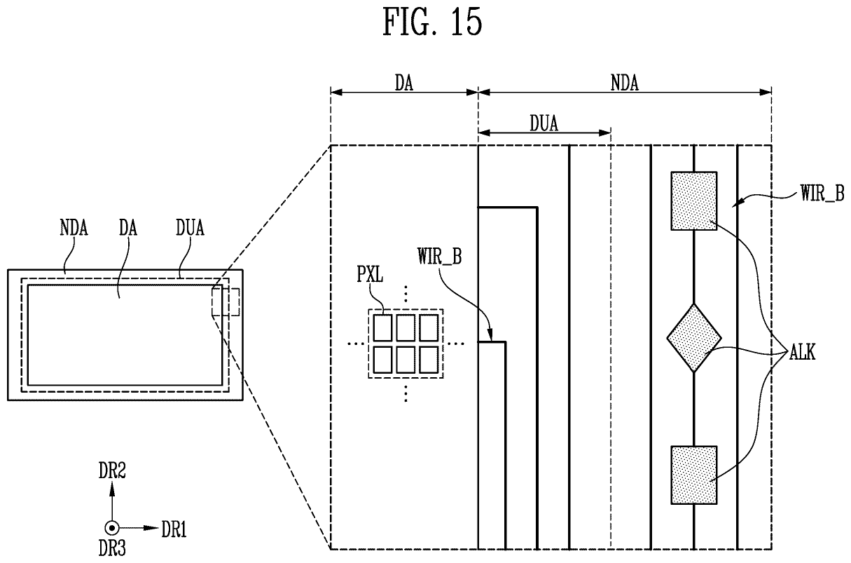

FIG. 15 is a schematic plan view illustrating a backplane wire WIR_B and alignment keys ALK in accordance with an embodiment. FIG. 15 illustrates a plan view schematically illustrating the display device DD, and a schematic enlarged view illustrating the display area DA and the non-display area NDA.

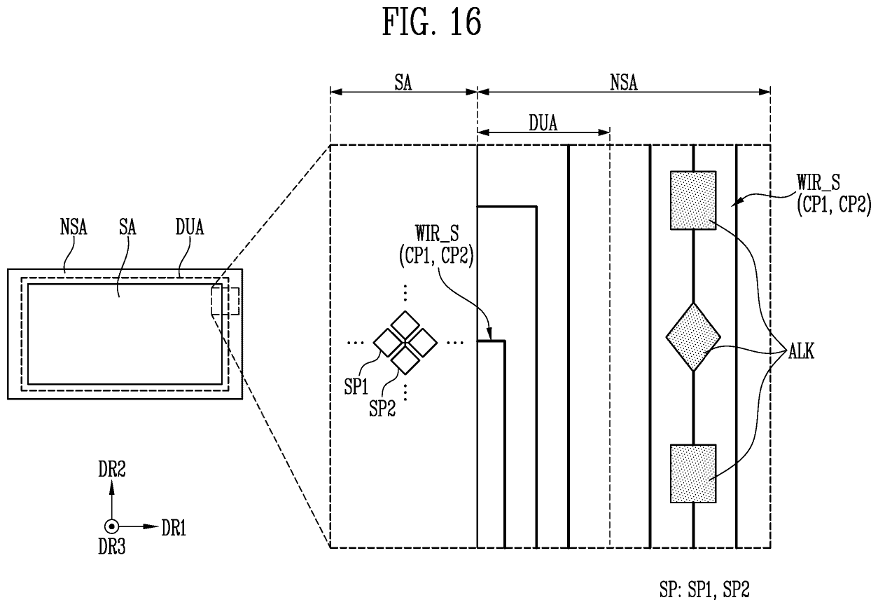

FIG. 16 is a schematic plan view illustrating a sensing wire WIR_S and alignment keys ALK in accordance with an embodiment. FIG. 16 illustrates a plan view schematically illustrating the display device DD, and a schematic enlarged view illustrating the sensing area SA and the non-sensing area NSA.

Referring to FIGS. 10 to 16, the pixels PXL in the display area DA may include the first pixel PXL1 and the second pixel PXL2 spaced apart from each other in one direction.

In an embodiment, each of the 1-1-th sub-pixel SPX1-1, the 2-1-th sub-pixel SPX2-1, and the 3-1-th sub-pixel SPX3-1 may form one sub-pixel area, and may provide light of a single color. Each of the 1-2-th sub-pixel SPX1-2, the 2-2-th sub-pixel SPX2-2, and the 3-2-th sub-pixel SPX3-2 may form one sub-pixel area, and provide light of a single color.

In an embodiment, the light blocking layer LBP may include a first light blocking part LBP_F and a second light blocking part LBP_S.

The first light blocking part LBP_F may be disposed around peripheries of the sub-pixels SPX1-1, SPX2-1, and SPX3-1 of the first pixel PXL1. For example, the first light blocking part LBP_F may enclose the entirety of each of the sub-pixels SPX1-1, SPX1-2, and SPX1-3 in a plan view. The first light blocking part LBP_F may have a closed-loop structure.

In an embodiment, a first portion of the first light blocking part LBP_F may extend in the first direction DR1, and a second portion of the first light blocking part LBP_F may extend in the second direction DR1 different from (e.g., crossing) the first direction DR1. Accordingly, when the first pixel PXL1 provides light, the first portion of the first light blocking part LBP_F that extends in the first direction DR1 may restrict a light path directed toward an upper side or a lower side. When the first pixel PXL1 provides light, the second portion of the first light blocking part LBP_F that extends in the second direction DR2 may restrict a light path directed toward a left side or a right side.

Therefore, when the display device DD is operated in the first mode, and thus, the first pixel PXL1 provides light, the provided light may have a limited viewing angle towards the sideways, and may output or substantially output light towards the front. While the first pixel PXL1 provides light, the first light blocking part LBP_F restricts the viewing angle of the light, and thus, may make it difficult for the driver to visually perceive the light. Furthermore, when the display device DD is operated in the first mode, and thus, the first pixel PXL1 provides light, the provided light may have a limited viewing angle in the upward direction, thereby reducing the risk of generating the reflective image information IMA_R.

The second light blocking part LBP_S may be disposed around peripheries of the sub-pixels SPX1-2, SPX2-2, and SPX3-2 of the second pixel PXL2. For example, the second light blocking part LBP_S may be open on at least one side of the sub-pixels SPX1-2, SPX1-2, and SPX1-3 in a plan view.

In an embodiment, the second light blocking part LBP_S may extend in the first direction DR1. The second light blocking part LBP_S may not extend in the second direction DR2. As the second light blocking part LBP_S extends in the first direction DR1, the second light blocking part LBP_S may cover an upper side of the sub-pixels SPX1-2, SPX2-2, and SPX3-2, while the remaining left and right sides OS of the sub-pixels SPX1-2, SPX2-2, and SPX3-2 are open. For example, the second pixel PXL2 may include first sides S1 in the first direction DR1 and second sides S2 in the second direction DR2. The second light blocking part LBS_S allows the first sides S1 of the first pixel PXL1 to be open, and may enclose the second sides S2. Accordingly, when the second pixel PXL2 provides light, the second light blocking part LBP_S that extends in the first direction DR1 may restrict a light path directed toward the upper side or the lower side.

As a result, when the display device DD is operated in the second mode, and thus, the second pixel PXL2 provides light, the provided light may have a limited viewing angle in the upward direction, thereby reducing the risk of generating the reflective image information IMA_R.

Referring to FIG. 11, the display layer DL may include the light emitting elements LD disposed on the base layer BSL. In an embodiment, the light emitting elements LD may be disposed in the sub-pixels SPX1-1, SPX2-1, and SPX3-1, respectively.

The touch sensor layer TSP may be disposed on the display layer DL. The touch sensor layer TSP may include a first interlayer insulating layer ILD1, a first conductive pattern layer CP1, a second interlayer insulating layer ILD2, a second conductive pattern layer CP2, and a third interlayer insulating layer ILD3.

The first interlayer insulating layer ILD1 may form a base on which the conductive pattern layers CP1 and CP2 are disposed. The second interlayer insulating layer ILD2 may be disposed between the first conductive pattern layer CP1 and the second conductive pattern layer CP2. The third interlayer insulating layer ILD3 may cover the second conductive pattern layer CP2.

In an embodiment, the first conductive pattern layer CP1 and the second conductive pattern layer CP2 may be patterned according to a desired structure (e.g., a certain or predetermined structure), and may form the sensing electrodes SP. For example, the second conductive pattern layer CP2 may be patterned into a mesh structure to form cells of the first and second sensing electrodes SP1 and SP2, and a portion of the second conductive pattern layer CP2 may be cut, and thus, enabling the first and second sensing electrodes SP1 and SP2 to be separated from each other. Furthermore, a portion of at least one of the first conductive pattern layer CP1 or the second conductive pattern layer CP2 may form a bridge for the first and second sensing electrodes SP1 and SP2.

In an embodiment, the first conductive pattern layer CP1 and the second conductive pattern layer CP2 may include various suitable conductive materials. The first to third interlayer insulating layers ILD1 to ILD3 may include organic materials or inorganic materials.

In an embodiment, the first conductive pattern layer CP1 and the second conductive pattern layer CP2 may be disposed in a non-sub-pixel area NSPA in a plan view. The non-sub-pixel area NSPA may be an area formed between the sub-pixels SPX, and may be an area where no light is visible.

The light controlling layer LCL may include light blocking layers LBP, passivation layers PAS, protective layers PVX, insulating layers INS, and a cover layer CVL, which are disposed in different layers, respectively.

In an embodiment, as described above, the light blocking layers LBP may be structures for controlling a light output path of light provided from the display layer DL, and may be disposed in a plurality of layers, respectively. In an embodiment, the number of layers in which the light blocking layers LBP are disposed is not particularly limited. Hereinafter, for convenience of illustration, the light blocking layers LBP may be described in more detail hereinafter as being disposed in four layers, respectively, as a representative example.

In an embodiment, the light blocking layers LBP may be disposed in the non-sub-pixel area NSPA. Each of the passivation layers PAS may form a base on which the corresponding light blocking layer LBP is disposed. Each of the protective layers PVX may cover the corresponding light blocking layer LBP. Each of the insulating layers INS may be disposed on the corresponding protective layer PVS, and may generally have a relatively large thickness.

The passivation layers PAS may include a first passivation layer PAS1, a second passivation layer PAS2, a third passivation layer PAS3, and a fourth passivation layer PAS4. The protective layers PVX may include a first protective layer PVX1, a second protective layer PVX2, and a third protective layer PVX3. The insulating layers INS may include a first insulating layer INS1, a second insulating layer INS2, and a third insulating layer INS3.

In an embodiment, the first passivation layer PAS1, the first light blocking layer LBP1, the first protective layer PVX1, and the first insulating layer INS1 may be disposed on the touch sensor layer TSP. The second passivation layer PAS2, the second light blocking layer LBP2, the second protective layer PVX2, and the second insulating layer INS2 may be disposed on the first insulating layer INS1. The third passivation layer PAS3, the third light blocking layer LBP3, the third protective layer PVX3, and the third insulating layer INS3 may be disposed on the second insulating layer INS2. The fourth passivation layer PAS4, the fourth light blocking layer LBP4, and the cover layer CVL may be disposed on the third insulating layer INS3.

In an embodiment, among the light blocking layers LBP, the light blocking layer LBP positioned in a layer closest to the display panel DP may be referred to as a bottom light blocking layer LBP_B. For example, in the present embodiment, the first light blocking layer LBP1 may be the bottom light blocking layer LBP_B.

In an embodiment, among the light blocking layers LBP, the light blocking layer LBP positioned in a layer closest to the window layer WD may be referred to as a top light blocking layer LBP_U. For example, in the present embodiment, the fourth light blocking layer LBP4 may be the top light blocking layer LBP_U.

In an embodiment, the passivation layers PAS, the protective layers PVX, the insulating layers INS, and the cover layer CVL may each include an organic material or an inorganic material. In an embodiment, the passivation layers PAS, the protective layers PVX, and the cover layer CVL may each include an inorganic material, and the insulating layers INS may include an organic material. However, the present disclosure is not limited thereto.

In an embodiment, the polarization layer POL and the window layer WD may be disposed on the cover layer CVL.

Referring to FIGS. 12 to 16, a cross-sectional structure of the display device DD spanning the display area DA and the non-display area NDA is illustrated.

In an embodiment, the alignment key layer ALK may not overlap with a conductive structure that floats, in a plan view.

In an embodiment, the display layer DL may include a backplane wire WIR_B disposed in the non-display area NDA. The backplane wire WIR_B may electrically connect a conductive structure (e.g., a pixel circuit) in the display area DA to the driving circuit part DCP.

The backplane wire WIR_B may be a component for electrically connecting conductive configurations to each other. The backplane wire WIR_B may not float, and may be electrically connected to a wiring of the pixel circuit PXC or the like in the display area DA.

The backplane wire WIR_B may have a linear structure. For example, the backplane wire WIR_B may not have an island shape. The backplane wire WIR_B may not have an isolated shape.

In an embodiment, the touch sensor layer TSP may include a sensing wire WIR_S disposed in the non-sensing area NSA. The sensing wire WIR_S may electrically connect a conductive structure (e.g., the sensing electrodes SP) in the sensing area SA to the driving circuit part DCP.

The sensing wire WIR_S may be a component for electrically connecting conductive configurations to each other. The sensing wire WIR_S may not float, and may be electrically connected to the sensing electrodes SP or the like in the sensing area SA.

In an embodiment, the sensing wire WIR_S may be formed by the first conductive pattern layer CP1 and/or the second conductive pattern layer CP2.

The sensing wire WIR_S may have a linear structure. For example, the sensing wire WIR_S may not have an island shape. The sensing wire WIR_S may not have an isolated shape.

In an embodiment, the display device DD may include dams DAM disposed on the touch sensor layer TSP in the non-display area NDA. The dams DAM may include structures formed through a same process as those of at least some of the protective layers PVX and the passivation layers PAS.

The dams DAM may include a first dam DAM1, a second dam DAM2, a third dam DAM3, and a fourth dam DAM4, which are sequentially arranged along a direction from the display area DA to the non-display area NDA. The dams DAM may prevent or substantially prevent materials from flowing outward when the protective layers PVX, the insulating layers INS, and the other layers are formed within the display area DA.

In an embodiment, the dummy light blocking layer LBP_D may be disposed in the dummy area DUA. In an embodiment, the dummy light blocking layer LBP_D may be patterned through a same process as that of the light blocking layers LBP formed in the display area DA. For example, the dummy light blocking layer LBP_D may include first to fourth dummy light blocking layers that are respectively formed through same processes as those of the first to fourth light blocking layers LBP1 to LBP4.

In an embodiment, the alignment key layer ALK may be disposed in a same layer as that of at least some of the light blocking layers LBP. The alignment key layer ALK may be patterned through a same process as that of at least some layers of the light blocking layers LBP, and may include a same material. In other words, alignment keys of the alignment key layer ALK for aligning layers formed after the light controlling layer LCL is manufactured may be formed when the light controlling layer LCL is manufactured.

In this case, the alignment keys for aligning the layers formed after the light controlling layer LCL is manufactured may be formed without the need or use for separate processes. In other words, the processes may be simplified, and the production costs may be reduced.

In an embodiment, the light blocking layers LBP, the alignment key layer ALK, and the dummy light blocking layers LBP_D may include a light blocking material (e.g., a material that blocks visible light). For example, the light blocking layers LBP, the alignment key layer ALK, and the dummy light blocking layers LBP_D may include black matrix material, such as carbon black. In an embodiment, the light blocking layers LBP, the alignment key layer ALK, and the dummy light blocking layers LBP_D may include an organic black material (e.g., a lactam-based material).

In another embodiment, the alignment key layer ALK and some of the light blocking layers LBP that are patterned through the same process as that of the alignment key layer ALK may include an organic black material (e.g., a lactam-based material), while some of the light blocking layers LBP that are patterned through a process different from that of the alignment key layer ALK may include a black matrix material, such as carbon black.

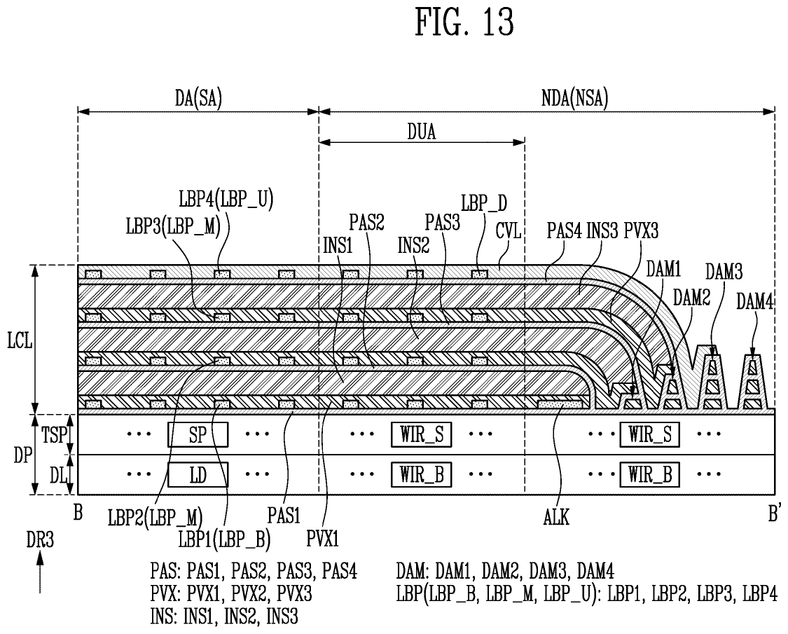

In some embodiments (e.g., refer to FIGS. 12 and 13), the alignment key layer ALK may be patterned through a same process as that of the bottom light blocking layer LBP_B at the same layer, and may include the same material as that of the bottom light blocking layer LBP_B.

In an embodiment, the alignment key layer ALK may be disposed on the first passivation layer PAS1 in the non-display area NDA other than the dummy area DUA.

In an embodiment, no structure patterned through a same process as the those of second to fourth light blocking layers LBP2 to LBP4 may be formed on the alignment key layer ALK.

In an embodiment, as the alignment key layer ALK is patterned through the same process as that of the bottom light blocking layer LBP_B, the alignment key layer ALK may be disposed on a more stable base. For example, as the alignment key layer ALK is directly disposed over the touch sensor layer TSP, the base on which the alignment key layer ALK is disposed may be flat or substantially flat.

Referring to FIG. 13, as the non-display area NDA is reduced (e.g., as the dead space is reduced), at least portions of the passivation layers PAS, the insulating layers INS, and the protective layers PVX that are disposed over the alignment key layer ALK may be bent. The passivation layers PAS, the insulating layers INS, and the protective layers PVX may include bent portions in an area overlapping with the alignment key layer ALK in a plan view. For example, in the non-display area NDA, the alignment key layer ALK may overlap with the bent portion of each of the passivation layers PAS, the insulating layers INS, and the protective layers PVX in a plan view. The alignment key layer ALK may be disposed on the first passivation layer PAS1 that is flat or substantially flat, rather than being formed on a bent base, whereby a structural stability of the alignment key layer ALK may be secured, and the window layer WD may be suitably aligned. Moreover, in this case, the non-display area NDA may be reduced, and thus, the display device DD may have an expanded display area DA with a larger surface area.

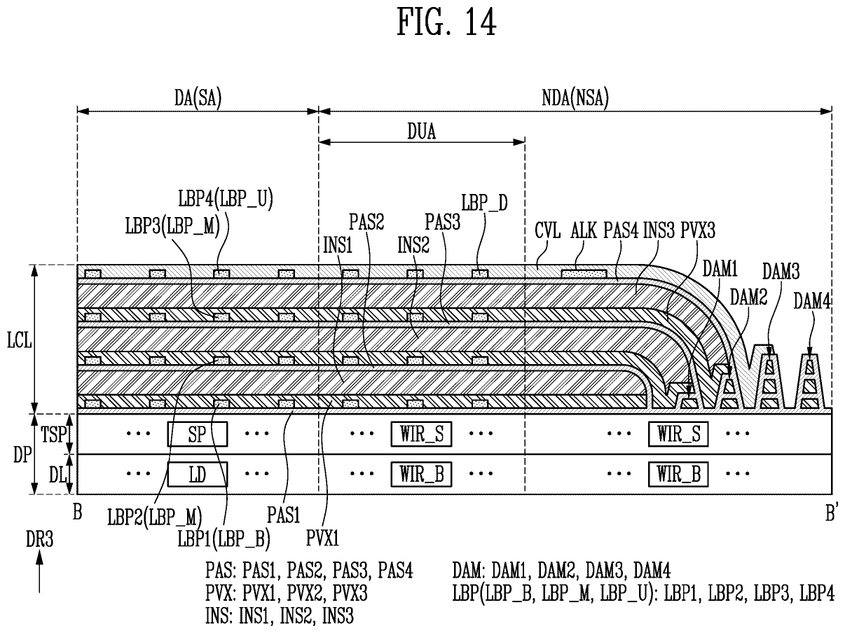

In an embodiment (e.g., refer to FIG. 14), the alignment key layer ALK may be patterned through a same process as that of the top light blocking layer LBP_U at the same layer, and may include a same material as that of the top light blocking layer LBP_U.

In an embodiment, the alignment key layer ALK may be disposed on the fourth passivation layer PAS4 in the non-display area NDA other than the dummy area DUA. In an embodiment, no structure patterned through a same process as that of the first to third light blocking layers LBP1 to LBP3 may be formed under the alignment key layer ALK.

In an embodiment, because the alignment key layer ALK is patterned through the same process as that of the top light blocking layer LBP_U, a light loss may be prevented or substantially prevented when light is applied to discern the window layer WD, and the alignment key layer ALK may be recognized with a higher reliability to align the window layer WD.

In an embodiment, the alignment key layer ALK may be a pattern or a mark formed at a suitable position (e.g., a predetermined position), and may have a recognizable shape. For example, the alignment key layer ALK may have various suitable polygonal shapes. However, the present disclosure is not limited thereto.

In an embodiment (e.g., refer to FIG. 15), the alignment key layer ALK may not overlap with a conductive structure having an isolated shape (e.g., an island shape) in the display layer DL in a plan view. In an embodiment, the alignment key layer ALK may or may not overlap with the backplane wire WIR_B having a linear structure, in a plan view. In this case, because no structures that could be confused with the alignment key layer ALK are placed in the non-display area NDA, an alignment reliability of the configurations formed after the alignment key layer ALK is formed may be improved.

In an embodiment (e.g., refer to FIG. 16), the alignment key layer ALK may not overlap with a conductive structure having an isolated shape (e.g., an island shape) in the touch sensor layer TSP in a plan view. In an embodiment, the alignment key layer ALK may or may not overlap with the sensing wire WIR_S having a linear structure, in a plan view. In this case, because no structures that could be confused with the alignment key layer ALK are placed in the non-sensing area NSA, an alignment reliability of the configurations formed after the alignment key layer ALK is formed may be improved.

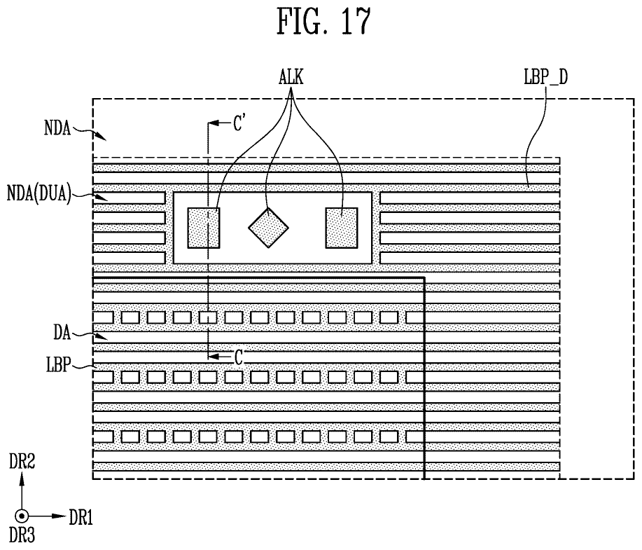

Hereinafter, a display device DD in accordance with some embodiments will be described in more detail with reference to FIGS. 17 to 19. For convenience, the same or substantially the same components and configurations as those described above may be briefly described hereinafter, or redundant description thereof may not be repeated.

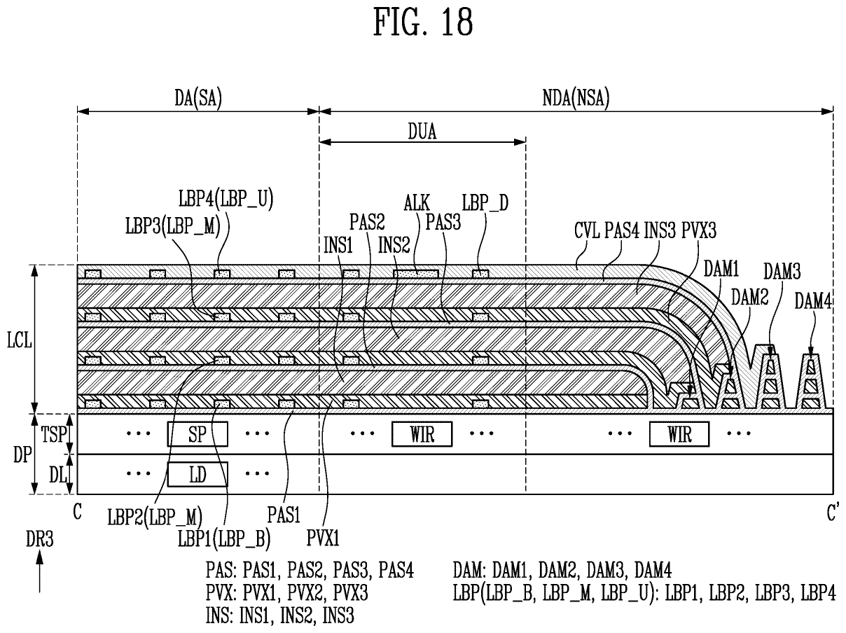

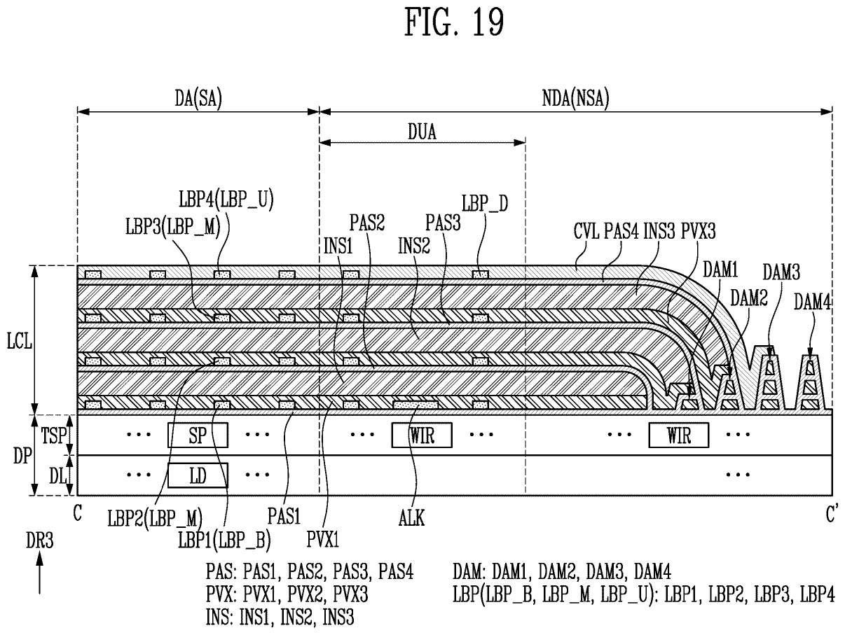

FIG. 17 is a schematic plan view illustrating the display device DD in accordance with an embodiment. FIG. 17 illustrates a light blocking layer LBP in the display area DA and the non-display area NDA, and layers patterned through a same process as that of the light blocking layer LBP in accordance with an embodiment. FIGS. 18 and 19 are schematic sectional views taken along the line C-C′ of FIG. 17.

The display device DD illustrated in FIGS. 17 to 19 may be different from the display device DD described above, in that an alignment key layer ALK having an embossed pattern may be disposed in the dummy area DUA.

In accordance with the present embodiment, the alignment key layer ALK may be disposed in the dummy area DUA, and may have an embossed pattern to form a recognizable structure (e.g., a certain or predetermined recognizable structure).

For example, the alignment key layer ALK may be adjacent to the dummy light blocking layer LBP_D in the dummy area DUA. For example, the dummy light blocking layer LBP_D may be patterned to extend predominantly in one direction, and may not be positioned in some areas (e.g., certain or predetermined areas) in the dummy area DUA. The alignment key layer ALK may be patterned in the areas in the dummy area DUA where the dummy light blocking layer LBP_D is not positioned.

In an embodiment (e.g., refer to FIG. 18), the alignment key layer ALK may be patterned through a same process as that of the top light blocking layer LBP_U in the dummy area DUA, and may be disposed in the same layer as that of the top light blocking layer LBP_U.

In an embodiment (e.g., refer to FIG. 19), the alignment key layer ALK may be patterned through a same process as that of the bottom light blocking layer LBP_B in the dummy area DUA, and may be disposed in the same layer as that of the bottom light blocking layer LBP_B.

In an embodiment, because the alignment key layer ALK is patterned through the same process as that of the light blocking layer LBP, the process may be simplified. In addition, because the alignment key layer ALK may be patterned in the dummy area DUA, the non-display area NDA may be further reduced. Accordingly, the dead space may be further reduced.

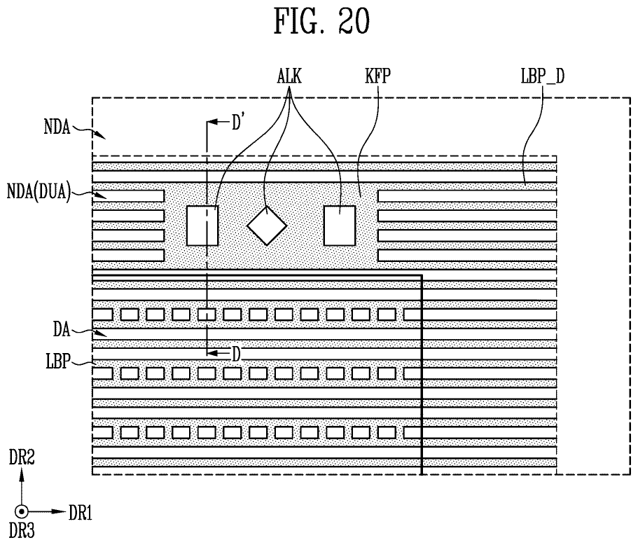

Hereinafter, a display device DD in accordance with some embodiments will be described in more detail with reference to FIGS. 20 to 22. For convenience, the same or substantially the same components and configurations as those described above may be briefly described hereinafter, or redundant description thereof may not be repeated.

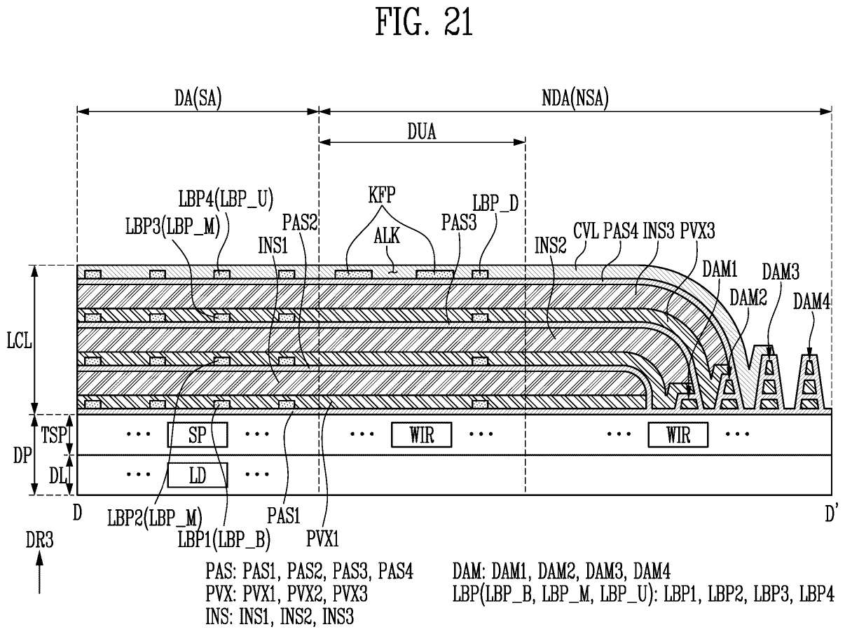

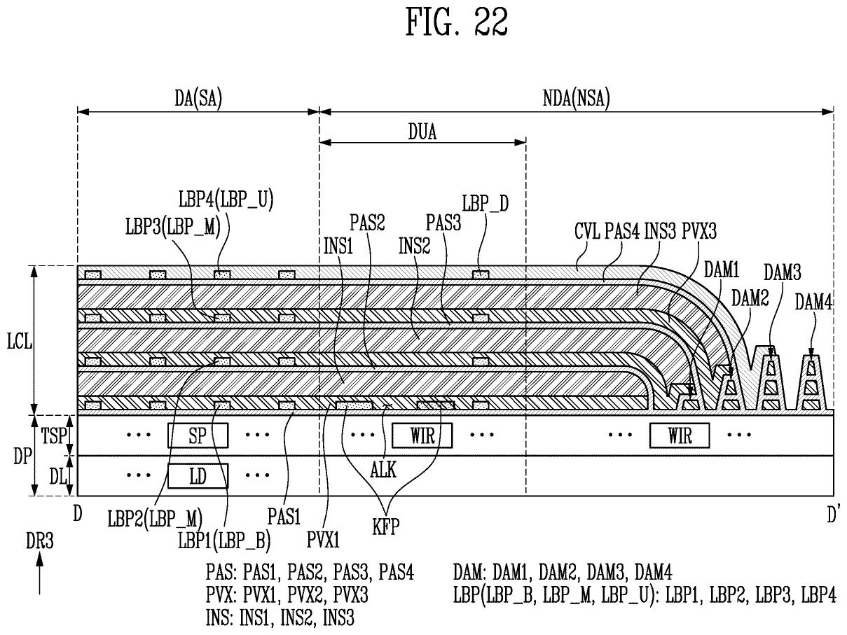

FIG. 20 is a schematic plan view illustrating the display device DD in accordance with an embodiment. FIG. 20 illustrates a light blocking layer LBP in the display area DA and the non-display area NDA, and layers patterned through a same process as that of the light blocking layer LBP in accordance with an embodiment. FIGS. 21 and 22 are schematic sectional views taken along the line D-D′ of FIG. 20.

The display device DD illustrated in FIGS. 20 to 22 may be different from the display device DD described above, in that the alignment key layer ALK having an intaglio pattern may be disposed in the dummy area DUA.

In accordance with the present embodiment, the alignment key layer ALK may be disposed in the dummy area DUA, and may have an intaglio pattern to form a recognizable structure (e.g., a certain or predetermined recognizable structure).

For example, the alignment key layer ALK may be adjacent to the dummy light blocking layer LBP_D in the dummy area DUA. For example, the dummy light blocking layer LBP_D may be patterned to extend predominantly in one direction, and may not be positioned in some areas (e.g., certain or predetermined areas) in the dummy area DUA. The alignment key layer ALK may be formed by an alignment key forming portion KFP patterned in the areas in the dummy area DUA where the dummy light blocking layer LBP_D is not positioned. For example, the alignment key forming portion KFP may be disposed to enclose a recognition pattern (e.g., a certain or predetermined recognition pattern) in order to define the alignment key layer ALK.

In an embodiment (e.g., refer to FIG. 21), the alignment key forming portion KFP for forming the alignment key layer ALK may be patterned through a same process as that of the top light blocking layer LBP_U in the dummy area DUA, and may be disposed in a same layer as that of the top light blocking layer LBP_U.

In an embodiment (e.g., refer to FIG. 22), the alignment key forming portion KFP for forming the alignment key layer ALK may be patterned through a same process as that of the bottom light blocking layer LBP_B in the dummy area DUA, and may be disposed in a same layer as that of the bottom light blocking layer LBP_B.

In an embodiment, because the alignment key forming portion KFP for forming the alignment key layer ALK is patterned through the same process as that of the light blocking layer LBP, the process may be simplified. In addition, because the alignment key forming portion KFP for forming the alignment key layer ALK may be patterned in the dummy area DUA, the non-display area NDA may be further reduced. Accordingly, the dead space may be further reduced.

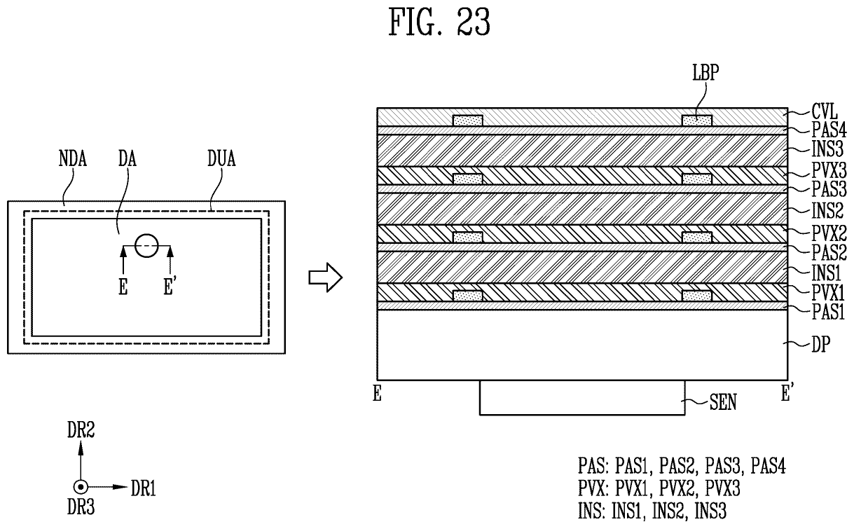

Hereinafter, a display device DD in accordance with an embodiment will be described in more detail with reference to FIG. 23. For convenience, the same or substantially the same components and configurations as those described above may be briefly described hereinafter, or redundant description thereof may not be repeated.

FIG. 23 illustrates a schematic plan view and a sectional view of a sensor SEN and a structure adjacent to the sensor SEN in accordance with an embodiment. FIG. 23 shows a plan view schematically illustrating the display device DD and a schematic sectional view taken along the line E-E′.

In an embodiment, the display device DD may include the sensor SEN to acquire sensing information based on various light information. For example, the sensor SEN may be disposed under the display panel DP in some areas (e.g., in certain or predetermined areas) in the display area DA.

The sensor SEN may be any one of various suitable sensors to acquire sensing information based on an applied light. For example, the sensor SEN may include at least one of an optical fingerprint sensor, an illumination sensor, a proximity sensor, a camera module (e.g., an image sensor or a camera), or a light sensor.

In an embodiment, because the sensor SEN outputs sensing information based on light applied from the outside, the intensity of the applied light may not be diminished by the light blocking layer LBP or the like.

In an embodiment, a portion of the sensor SEN may not overlap with the light blocking layer LBP in a plan view. Accordingly, a sensing sensitivity of the sensor SEN may be improved.

In an embodiment, the light blocking layer LBP may include carbon black or the like. In an embodiment, to enhance the sensing sensitivity of the sensor SEN, the light blocking layer LBP may include an organic black material (e.g., a lactam-based material). In this case, because the organic black material (e.g., the lactam-based material) may transmit light in the infrared wavelength band, the light blocking layer LBP may appropriately perform a viewing angle control function for visible light, while also ensuring excellent sensing sensitivity of the sensor SEN.

In this case, because the alignment key layer ALK according to an embodiment may be formed through the same process as that of the light blocking layer LBP, the alignment key layer ALK may also include the organic black material (e.g., the lactam-based material).

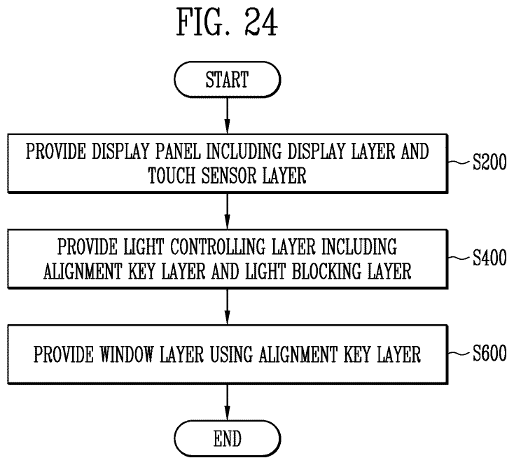

A method of manufacturing the display device DD in accordance with an embodiment will be described in more detail hereinafter with reference to FIGS. 24 to 27. For convenience, the same or substantially the same components and configurations as those described above may be briefly described hereinafter, or redundant description thereof may not be repeated.

FIG. 24 is a flowchart illustrating a method of manufacturing the display device DD in accordance with an embodiment.

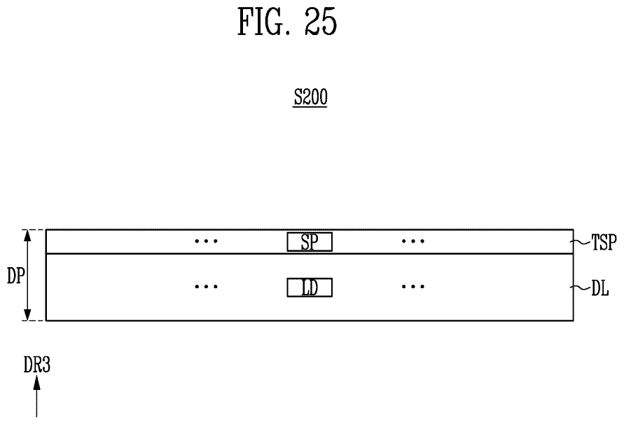

FIGS. 25 through 27 are schematic sectional views illustrating some processes of the method of manufacturing the display device DD in accordance with an embodiment. For convenience of illustration, FIGS. 25 to 27 are provided based on the cross-sectional structure described above with reference to FIG. 2.

Referring to FIG. 24, the method of manufacturing the display device DD in accordance with an embodiment may start, and a display panel including a display layer and a touch sensor layer may be provided (S200), a light controlling layer including an alignment key layer and a light blocking layer may be provided (S400), a window layer using the alignment key layer may be provided (S600), and the method may end.

Referring to FIGS. 24 and 25, at S200 of providing the display panel including the display layer and the touch sensor layer, the display layer DL and the touch sensor layer TSP on the display layer DL may be provided.

In S200, the light emitting elements LD may be disposed on the base layer BSL, thus forming the display layer DL. The sensing electrodes SP may be disposed on the display layer DL, thus forming the touch sensor layer TSP.

In an embodiment, the conductive layers or the insulating layers on the base layer BSL may be formed based on a suitable process for manufacturing a semiconductor device as would be understood by those having ordinary skill in the art. For example, the conductive layers or the insulating layers on the base layer BSL may be formed through a photolithography process, may be etched by various suitable methods (e.g., wet etching, dry etching, or the like), and may be deposited by various suitable methods (e.g., sputtering, chemical vapor deposition, or the like). However, the present disclosure is not limited thereto.

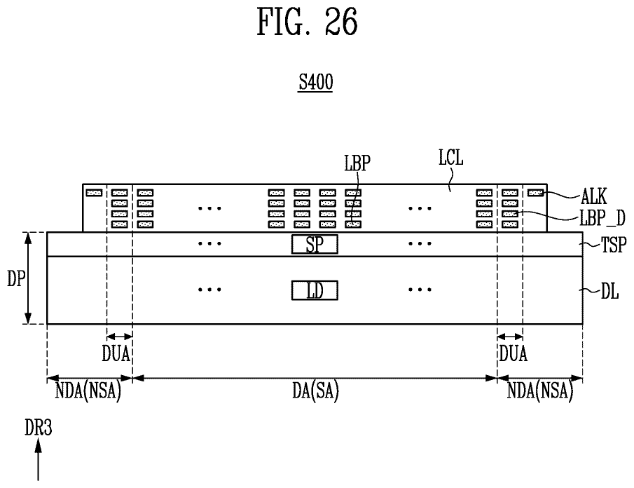

Referring to FIGS. 24 and 26, at S400 of providing a light controlling layer including an alignment key layer and a light blocking layer, the light blocking layer LBP may be formed in the display area DA, the dummy light blocking layer LBP_D may be formed in the dummy area DUA, and the alignment key layer ALK may be formed in the non-display area NDA.

In S400, the light blocking layer LBP, the dummy light blocking layer LBP_D, and the alignment key layer ALK may be concurrently or substantially simultaneously formed with each other through the same process as each other. In some embodiments, the alignment key layer ALK may be formed in the dummy area DUA, and may be formed at a relatively upper side or a relatively lower side.

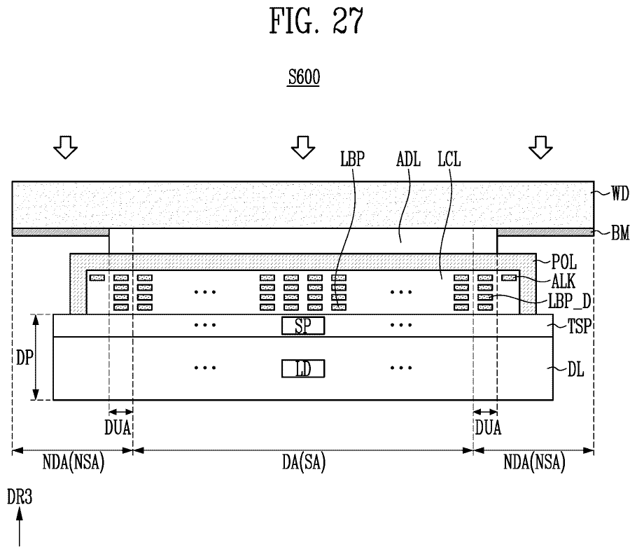

Referring to FIGS. 24 and 27, at S600 of providing the window layer using the alignment key layer, the polarization layer POL may be disposed on the light controlling layer LCL, and the window layer WD may be aligned using the alignment key layer ALK.

In S600, the alignment position of the window layer WD may be determined by the alignment key layer ALK formed on the light controlling layer LCL. In an embodiment, because the polarization layer POL may be disposed on the light controlling layer LCL, the position of the alignment key layer ALK may be discerned using light that passes through the polarization layer POL. As such, the window layer WD may be aligned on the display panel DP and the light controlling layer LCL. For example, to discern the position of the alignment key layer ALK, light with a wavelength ranging from 700 nm to 900 nm may be used. For example, the light used to discern the position of the alignment key layer ALK may have a wavelength ranging from 750 nm to 850 nm.

In S600, the black matrix layer BM and the adhesive layer ADL may be interposed between the window layer WD and the light controlling layer LCL, and the window layer WD may be suitably aligned, and thus, an outer component of the display device DD may be formed.

As described above, the alignment key layer ALK for the layers such as the window layer WD provided after the light controlling layer LCL is formed may be embedded in the light controlling layer LCL, thereby enhancing a process convenience.

A display device according to an embodiment is applicable to an electronic device. In an embodiment, an electronic device 10 includes the above-described display device DD and may further include other modules or devices having additional functions in addition to the display device DD.

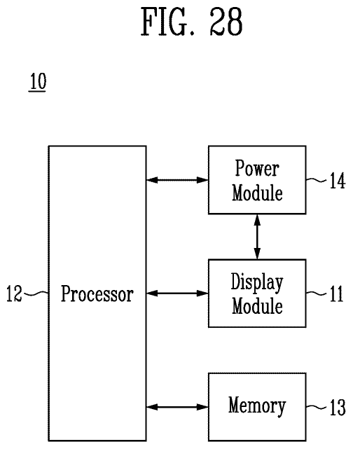

FIG. 28 is a block diagram of an electronic device according to an embodiment. Referring to FIG. 28, the electronic device 10 may include a display module 11, a processor 12, a memory 13, and a power module 14.

The processor 12 may include at least one of a central processing unit (CPU), an application processor (AP), a graphic processing unit (GPU), a communication processor (CP), an image signal processor (ISP), and a controller. The memory 13 may store data and/or information used to operate the processor 12 or the display module 11. When the processor 12 executes an application stored in the memory 13, image data signals and/or input control signals may be transferred to the display module 11. The display module 11 may process the provided signals and output image information on a display screen.

The power module 14 may include a power supply module, such as a power adapter or a battery device, and a power conversion module. The power conversion module converts power supplied by the power supply module and generates power to operate the electronic device 10.

At least one of the above-described components of the electronic device 10 may be included in the display device DD according to embodiments as described above. In addition, in terms of functionality, some of the individual modules included in one module may be included in the display device DD and others may be provided separately from the display device DD. For example, the display module 11 is included in the display device DD, whereas the processor 12, the memory 13, and the power module 14 are not included in the display device and are instead provided separately in the electronic device 10.

Some embodiments of the present disclosure may provide a display device and a method of manufacturing the display device, in which a manufacturing process may be simplified, thereby reducing production costs.

Some embodiments of the present disclosure may provide a display device and a method of manufacturing the display device, which may enhance a user safety and improve visibility characteristics, so that the display device may be suitably applied to in-vehicle infotainment systems.

Some embodiments of the present disclosure may provide a display device and a method of manufacturing the display device, in which an alignment key for performing a manufacturing process may be suitably provided.

Some embodiments of the present disclosure may provide a display device and a method of manufacturing the display device, in which a dead space may be reduced, thus allowing a visible surface area to be expanded.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

What is claimed is:

1. A display device, comprising:
a display panel comprising a first pixel, and a second pixel spaced from the first pixel;
a light controlling layer on the display panel, and comprising an alignment key layer, and light blocking layers comprising a first light blocking part and a second light blocking part; and
a window layer on the light controlling layer,
wherein the first light blocking part encloses an entirety of the first pixel in a plan view,
wherein the second light blocking part is opened at a first side of the second pixel in a first direction, and encloses a second side of the first pixel in a second direction different from the first direction,
wherein the display device is configured to operate in a first mode in which the first pixel is configured to provide light, or a second mode in which the second pixel is configured to provide light, and
wherein the alignment key layer is located in a same layer as that of at least one of the light blocking layers.

2. The display device of claim 1, wherein the window layer is configured to be aligned utilizing the alignment key layer.

3. The display device of claim 1, wherein the light blocking layers comprises a bottom light blocking layer adjacent to the display panel, and a top light blocking layer adjacent to the window layer.

4. The display device of claim 3, wherein the alignment key layer is located in a same layer as that of the bottom light blocking layer.

5. The display device of claim 4, wherein a structure in a same layer as those of the light blocking layers is not located over the alignment key layer.

6. The display device of claim 4, further comprising an insulating layer on the alignment key layer, the insulating layer comprising a bent portion in an area overlapping with the alignment key layer in a plan view.

7. The display device of claim 3, wherein the alignment key layer is located in a same layer as that of the top light blocking layer.

8. The display device of claim 1, further comprising:
a passivation layer as a base on which the light blocking layers are located;
a protective layer covering the light blocking layers; and
an insulating layer on the protective layer,
wherein the light blocking layers comprise four different layers.

9. The display device of claim 1, further comprising a display area, and a non-display area enclosing the display area,
wherein the alignment key layer does not overlap with a floating conductive structure in a plan view.

10. The display device of claim 1, further comprising a display area, and a non-display area enclosing the display area,
wherein the display panel comprises a backplane wire located in the non-display area, the backplane wire having a linear structure, and
wherein the alignment key layer does not overlap with a conductive structure having an island shape in a plan view.

11. The display device of claim 1, further comprising a sensing area, and a non-sensing area enclosing the sensing area,
wherein the display panel further comprises a display layer, and a touch sensor layer on the display layer, the touch sensor layer comprising a sensing electrode,
wherein the touch sensor layer further comprises a sensing wire in the non-sensing area, the sensing wire having a linear structure, and being electrically connected to the sensing electrode, and
wherein the alignment key layer does not overlap with a conductive structure having an island shape in a plan view.

12. The display device of claim 1, further comprising a display area, and a non-display area enclosing the display area,
wherein the non-display area comprises a dummy area around the display area,
wherein a dummy light blocking layer is located in the dummy area in a same layer as that of at least one of the light blocking layers, and
wherein the alignment key layer is located in the dummy area.

13. The display device of claim 12, wherein the alignment key layer comprises an embossed pattern or an intaglio pattern.

14. The display device of claim 1, wherein the light blocking layers comprise one or more of a black matrix material or an organic black material.

15. The display device of claim 14, wherein the alignment key layer and the at least one of the light blocking layers in the same layer as that of the alignment key layer comprise the black matrix material, and some of the light blocking layers that are in a different layer from that of the alignment key layer comprise the organic black material.

16. The display device of claim 1, further comprising:
a polarization layer between the light controlling layer and the window layer; and
a black matrix layer under the window layer,
wherein the black matrix layer and the alignment key layer overlap with each other in a plan view.

17. The display device of claim 1, wherein the display panel comprises a base layer, and
wherein the display device further comprises a sensor under the base layer in a display area.

18. The display device of claim 14, wherein the light blocking layer comprises a lactam-based material.

19. The display device of claim 1,
wherein the first light blocking part has a closed-loop shape, and
wherein the second light blocking part has a shape extending in one direction.

20. An electronic device comprising:
a processor configured to transfer an input control signal;
a display device configured to output an image information; and
a power module configured to supply a power to the display device,
wherein the display device includes:
a display panel comprising a first pixel, and a second pixel spaced from the first pixel;
a light controlling layer on the display panel, and comprising an alignment key layer, and light blocking layers comprising a first light blocking part and a second light blocking part; and
a window layer on the light controlling layer,
wherein the first light blocking part encloses an entirety of the first pixel in a plan view,
wherein the second light blocking part is opened at a first side of the second pixel in a first direction, and encloses a second side of the first pixel in a second direction different from the first direction,
wherein the display panel is configured to operate in a first mode in which the first pixel is configured to provide light, or a second mode in which the second pixel is configured to provide light, and
wherein the alignment key layer is located in a same layer as that of at least one of the light blocking layers.
